(19) United States
(12) Patent Application Publication
(10) Pub. No.: US 2025/0284051 A1
(43) Pub. Date: Sep. 11, 2025

(54) ACTIVE PHOTONIC INTEGRATED NONLINEAR CIRCUITS

(71) Applicant: California Institute of Technology, Pasadena, CA (US)

(72) Inventors: Benjamin K. Gutierrez, Redondo Beach, CA (US); Nicolas Englebert, Pasadena, CA (US); Alireza Marandi, Pasadena, CA (US)

(73) Assignee: California Institute of Technology, Pasadena, CA (US)

(21) Appl. No.: 19/072,822

(22) Filed: Mar. 6, 2025

Related U.S. Application Data
(60) Provisional application No. 63/562,157, filed on Mar. 6, 2024.

(51) Int. Cl. G02B 6/12; G02B 6/125

(52) U.S. Cl. CPC G02B 6/12004; G02B 6/125; G02B 2006/12104; G02B 2006/1214; G02B 2006/12142; G02B 2006/12147; G02B 2006/12159

(57) ABSTRACT

A photonic integrated circuit including at least one integrated optical gain section having a peak gain at a first frequency; and at least one nonlinear sub-circuit which is coupled to the optical gain section either evanescently or through edge coupling, wherein the nonlinear sub-circuit further comprises at least one nonlinear component comprising at least one of a waveguide or a resonator comprising second-order nonlinearity enabling generation of frequency components at least one octave below or above the first frequency, and the nonlinear sub-circuit is configured to provide at least one of nonlinear interferometry wherein the interferometer output depends on the input intensity to the nonlinear sub-circuit, or spectral broadening by extending the spectrum outside the gain spectrum of the gain section.

### CROSS REFERENCE TO RELATED APPLICATIONS

This application claims the benefit under 35 U.S.C. Section 119(e) of U.S. Provisional Application No. 63/562,157, filed Mar. 6, 2024, by Benjamin K. Gutierrez, Nicolas Englebert, and Alireza Marandi, entitled “ACTIVE PHOTONIC INTEGRATED NONLINEAR CIRCUITS,” (CIT-9139-P) which application is incorporated by reference herein.

### STATEMENT REGARDING FEDERALLY SPONSORED RESEARCH AND DEVELOPMENT

This invention was made with government support under Grant No(s). ECCS1846273 & CCF1918549 awarded by the National Science Foundation, under Grant No. FA9550-23-1-0755 awarded by AFOSR and Grant No. D23AP00158-00 awarded by the Department of the Interior. The government has certain rights in the invention

### BACKGROUND OF THE INVENTION

### Field of the Invention

The present disclosure relates to photonic integrated circuits and methods of making and using the same.

### Description of the Related Art

Current photonic integrated circuits have limited functionality. There is a need for photonic integrated circuits designed for various applications in spectroscopy, quantum computing, and optical communications. The present disclosure satisfies this need.

### SUMMARY OF THE INVENTION

Illustrative embodiments of the inventive subject matter disclosed herein include, but are not limited to, the following.

A photonic integrated circuit comprising:
at least one integrated optical gain section having a peak gain at a first frequency; and
at least one nonlinear sub-circuit which is coupled to the optical gain section either evanescently or through edge coupling, wherein:
the nonlinear sub-circuit further comprises:
at least one nonlinear component comprising at least one of a waveguide or a resonator comprising second-order nonlinearity enabling generation of frequency components at least one octave below or above the first frequency, and
the nonlinear sub-circuit is configured to provide (i.e., one or a combination of the following functions):
   (a) nonlinear interferometry, wherein the interferometer output depends on the input intensity to the nonlinear sub-circuit, and/or
   (b) spectral broadening by extending the spectrum outside the gain spectrum of the gain section.

The circuit of clause 1, wherein the optical gain section comprises a semiconductor optical amplifier which is electrically pumped.

The circuit of clause 1 wherein the optical gain section comprises a rare-earth doped material which is optically pumped.

The circuit of clause 1, wherein the nonlinear sub-circuit comprises the nonlinear component comprising a section configured to provide phase matching or a certain level of phase mismatch for one or a plurality of quadratic nonlinear processes such as second-harmonic generation, difference-frequency generation, sum-frequency generation, or optical parametric amplification.

The circuit of clause 4, wherein the nonlinear component comprises a section made of a ferroelectric material, such as lithium niobate or lithium tantalate or barium titanate, and the phase matching is provided by periodic or aperiodic poling of the ferroelectric domains of the ferroelectric material.

The circuit of clause 1, wherein the nonlinear sub-circuit comprises a Michelson interferometer comprising
a two-by-two coupler comprising coupler ports wherein two of the coupler ports are terminated by mirrors, such as partial or almost perfect loop mirrors or Bragg reflectors, and at least one of the arms of the interferometer comprises the waveguide comprising a waveguide section with the second order (quadratic) nonlinearity configured to provide phase matched or phase mismatched second-harmonic generation in the vicinity of the first frequency. [FIG. 4A]

The circuit of clause 1, wherein the nonlinear subcircuit comprises a Mach-Zehnder interferometer comprising:
two two-by-two couplers which are connected to each other in series via connecting waveguide, and one of the connecting waveguides includes the waveguide comprising a waveguide section with the second order (quadratic) nonlinearity configured to provide phase matched or phase mismatched second-harmonic generation in the vicinity of the first frequency. [FIGS. 4B,C]

The circuit of clause 7, wherein the Mach-Zehnder nonlinear interferometer is terminated by a partial or almost perfect loop mirror or other types of reflectors. [FIG. 4B]

The circuit of clause 7, wherein the Mach-Zehnder nonlinear interferometer is placed inside a laser resonator configured as a ring or linear resonator comprising the gain element. [FIG. 4C]

The circuit of clause 1, wherein the nonlinear sub-circuit comprises the at least one nonlinear component comprising at least two spectral broadening sections and two filters and is configured as a Mamyshev oscillator to generate short pulses. [FIG. 6]

The circuit of clauses 1-10, wherein the nonlinear sub-circuit further comprises an actuator, in the form of an electro-optic or thermo-optic or piezoelectric modulator.

The circuit of clause 11, wherein the actuator is an electrooptic modulator which is configured to be driven at frequencies from DC to 10's of GHz or a portion of this range.

The circuit of clause 1 wherein the nonlinear sub-circuit comprises an optical parametric oscillator.

The circuit of clause 1, wherein the nonlinear sub-circuit comprises a coupler for coupling to the resonator or the waveguide, the photonic integrated circuit further comprising at least one mode converter and at least one spatial filter coupled to match the spatial modes of electromagnetic pulses between the coupler, the gain section, and the nonlinear component comprising the waveguide.

The circuit of clause 1, wherein the one or a plurality of waveguides in the nonlinear sub-circuit are dispersion-engineered for specific group velocity dispersions and/or group velocity mismatch among different spectral contents of electromagnetic waves generated in the nonlinear sub-circuit to enable formation of electromagnetic pulses shorter than 100 ps in the circuit or spectra of the electromagnetic wave spanning beyond an octave.

The circuit of clause 1, wherein the nonlinear sub-circuit is configured to create a passively mode-locked laser generating electromagnetic pulses shorter than 20 ps.

The circuit of clause 1, wherein the nonlinear sub-circuit is configured to create an electro-optic frequency comb source wherein the source comprises a laser cavity comprising the gain element and one or a plurality of electro-optic modulators in the nonlinear sub-circuit.

The circuit of clause 1 wherein the spectral broadening is covering one octave or ⅔ of an octave, and the circuit is further configured to provide a self-referenced frequency comb through f-2f or 2f-3f interferometry.

The circuit of clause 1 wherein the non-linear sub-circuit comprises the resonator comprising parametrically driven active cavity comprising a coupler comprising wavelength selective coupler coupling the optical gain section to the waveguide configured to generate a half frequency of a pump, wherein the optical gain section is configured to amplify the half frequency and the coupler is designed to transmit the half frequency but not the pump inputted to the non-linear sub-circuit.

The circuit of clause 1, wherein the nonlinear sub-circuit is configured to support formation of solitons.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Referring now to the drawings in which like reference numbers represent corresponding parts throughout:

FIG. 1: Schematic of a photonic integrated circuit which includes an active component providing optical gain for a wavelength range centered around a certain wavelength.

FIGS. 2A-2C. An example of a passively mode-locked laser which includes an intracavity gain mechanism as well as an intracavity effective saturable absorber based on a second-order nonlinearity. (A) a ring cavity configuration, (B) a linear cavity configuration with dichroic splitter and independent monochromatic reflectors and (C) a linear cavity with a dichroic reflector.

FIGS. 3A-3B. An example of a passively mode-locked laser that includes an intracavity gain mechanism as well as a nonlinear optical loop mirror (NOLM) in two different configurations: “figure-eight” (A), and “figure-nine” (B).

FIGS. 4A-4C. A passively mode-locked laser includes an intracavity gain mechanism and a nonlinear interferometer (NLI) in three different configurations: (A) Linear cavity nonlinear Michelson interferometer. (B) Linear cavity nonlinear Mach-Zehnder interferometer. (C). Ring cavity nonlinear Mach-Zehnder interferometer.

FIGS. 5A-5B. A passively mode-locked laser includes an intracavity gain mechanism that acts in a nonlinear amplifying loop mirror (NALM). A) An NALM based on a third-order nonlinear phase accumulation. B) An NALM based on a second-order nonlinear phase accumulation.

FIGS. 6A-6B. A Mamyshev oscillator that implements an intracavity gain mechanism(s), intracavity spectral broadening regions based on PPLN, and intracavity spectrally selective filters. A) A ring configuration of the Mamyshev oscillator in which two intracavity gain mechanisms are implemented. B) A Mamyshev oscillator based on a linear resonator.

FIG. 7. A parametrically driven cavity that includes an intracavity gain mechanism as well as an intracavity second-order nonlinear section. The gain mechanism compensates for the losses in the cavity forming a high-Q subthreshold active cavity while the second-order section enables the formation of a background-free pulse.

FIG. 8. A pump-enhanced optical parametric oscillator in which an intracavity gain mechanism forms a laser at the pump frequency that further includes an intracavity second-order nonlinear (NL) section that is coupled from and to a ring cavity at either end of the NL section. This coupled ring cavity that surrounds the NL region implements spectral selective couplers which operate as short pass filters to couple out the signal and idler frequencies produced by the NL section, resulting in an OPO cavity that is independent of but attached to a part of the pump laser cavity.

FIG. 9 shows a nonlinear frequency conversion integrated device. Light in injected into a waveguide prior its amplification in a gain medium (here, an SOA). Since nonlinear effects depends on the power, this allows for efficient new frequency formation in a nonlinear section that directly follows the amplifier.

FIG. 10. An actively mode-locked laser that includes an intracavity gain mechanism as well as an intracavity modulator in a ring cavity (A) and in a linear cavity (B). The configuration can benefit from strong nonlinearity in the circuit for wavelength conversion and/or spectral broadening.

FIG. 11. shows an integrated pulse source, here an active mode-locked laser, see e.g., FIG. 10 followed by a nonlinear section. Part of the intracavity power is extracted and sent through a nonlinear section (here, a second-order nonlinear section) to broaden the frequency content. Such large broadening allows to fully reference of the output frequency comb through the f-2f technique and use it for several applications requiring high precision (metrology, optical clock, . . . ). The nonlinear broadening can also occurs inside of the laser cavity.

FIG. 12A. Equivalence between two ways of providing optical gain in a PIC. Left: the gain is directly added on the chip, and a reflector ensures a double-pass to the gain medium. Right: a gain medium is butt-coupled to a gain chip. As its left-facet is highly reflective, it ensures a double-pass in the gain medium.

FIG. 12B Photo of the actual gain chip (left) butt-coupled to the TFLM chip (right).

FIG. 12C. Electric field transverse profile in the gain chip (left) and in the TFLN chip (right) after the taper.

FIG. 12D. Passively mode-locked laser includes an intracavity gain mechanism and a nonlinear interferometer (NLI) in the linear cavity nonlinear Michelson interferometer.

FIGS. 13A-13B. Schematic of the two linear configurations of passively mode-locked laser experimentally studied: (A) Michelson and (B) MZI.

FIGS. 13C-13D. Simulation of the configuration depicted in FIG. 13A (top FIGS. 13C-D) and FIG. 13B (bottom FIG. 13C-D) with a phase-mismatched (left) and phase-matched (right) second-order nonlinear section.

FIGS. 13E-F Design of the passively mode-locked laser chip in the Michelson (E) and the MZI (F) configuration.

FIG. 13G. Design of the entire chip including the two designs (see (A)-(B)). The fabricated chip is shown in FIG. 12.

FIGS. 14A-14B. Experimental setup for the passively mode-locked laser. (A) Schematic of the experimental setup, showing the SOA butt-coupled to a TFLN nonlinear circuit incorporating a nonlinear interferometer configured as a passive mode-locking mechanism (see also FIGS. 12 and 13). The output of the circuit is collected through a lensed fiber which is then sent to an optical spectrum analyzer (OSA), an intensity autocorrelator (A.C.) and a photodiode (PD) whose signal is measured by an electrical spectrum analyzer (ESA). (B) Image of the experimental setup of the real-world passively mode-locked laser chip. The gain chip, TFLN chip, thermo-electrical cooler (TEC) and lensed fiber are all pointed out.

FIG. 15A shows autocorrelation of the passively mode-locked laser as the SOA drive current is swept

FIG. 15B shows corresponding spectra of the passively mode-locked laser as the SOA drive current is swept.

FIGS. 16A-16D. Results showing the passively mode-locked laser spectra (A,B) and their corresponding autocorrelation (C,D) of two predominate states observed.

FIG. 17. The spectrum and corresponding autocorrelation for a dense comb state. The inset shows a gaussian fit pulse duration of 3.71 ps FWHM.

FIG. 18. FDTD simulations of a curved directional coupler showing near 3 dB splitting over a 30 nm bandwidth centered at 1065 nm. This CDC a 700 nm gap, 800 nm top width, 600 μm radius of curvature and a length of 45 μm.

FIG. 19. A Sagnac loop reflector that implements a curved coupling region for broadband reflectivity.

FIG. 20. Measured power coupling of a CDC and its calculated reflection spectrum if used in a loop mirror.

FIG. 21. Microscope image of a periodically poled thin film lithium niobate wafer.

FIG. 22. Microscope images of an electro-optic phase modulator on TFLN. The electrodes are placed on top of a 800 nm thick cladding layer such that the electrodes may cross over the waveguide with minimal loss

FIG. 23. Diagram of an inverse taper on TFLN to and SOA.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

The present disclosure describes active nonlinear photonic integrated circuits comprising one or a plurality of components such as waveguides, couplers, spectral filters, spatial mode filters, mode converters, resonators, modulators, nonlinear waveguides, as well as integrated optical gain. Particularly, inventive embodiments of present disclosure are focused on integrated circuits utilizing second-order optical nonlinearity and optical gain in the circuits for a variety of functionalities and applications.

To construct the circuits described herein, a photonic integrated circuit (PIC) is fabricated on a certain material platform which particularly enables nonlinear photonic components. As used herein, the term “material platform” refers to any material or combination of materials used for integrated photonic devices. Examples of the material platform may include but are not limited to Silicon, Silicon Nitride, Indium Phosphide, Gallium Arsenide, Lithium Niobate, diamond, Silicon Dioxide, and Sapphire. This PIC may include one or a plurality of waveguides, couplers, spectral filters, resonators, modulators, or nonlinear waveguides which form the basis of the photonic circuit. The PIC further includes an active medium including optical gain.

There are many ways in which optical gain can be integrated into the circuits, which include but are not limited to, hybrid integration of an electrically pumped semiconductor gain and optical pumping of a gain section that incorporates rare-earth doping. Hybrid integration of semiconductor gain can be performed in at least two ways. Firstly, an edge-emitting or facet-emitting semiconductor gain may be directly coupled to the edge or facet of the photonic integrated circuit (PIC). In this case, the PIC may implement a mode-matching component designed to increase the optical power coupling between the gain and the PIC. For example, a photonic wire bond may be used to form a waveguide between the facets of the gain and the PIC, respectively. Another approach is to simply bring the facets of the gain and PIC close together, in a butt-coupled configuration, to facilitate optical coupling between the two. The second approach to hybrid integration of semiconductor gain involves evanescent coupling from the material platform to the gain region. In this case, the PIC may implement components designed to enhance the evanescent coupling between the gain and the PIC, such as a tapered waveguide. In the case of an optically pumped gain region incorporating rare earth doping, the material platform itself may be doped, or a doped material may be brought close enough to the PIC to facilitate evanescent coupling to that gain region. Depending on the gain implementation, different types of circuit configurations are possible. For example, a gain region that operates in transmission opens the possibility for ring configurations or inline amplification.

The PIC material platform may exhibit second-order nonlinearity or an electro-optic Pockels effect (e.g., Lithium Niobate), enabling homogeneous integration of modulators and nonlinear waveguides. However, suppose the PIC material platform does not include such capabilities. In that case, it is also possible to evanescently couple from one material platform to another that exhibits such capabilities, enabling heterogeneous integration of modulators and nonlinear waveguides. In another embodiment, the PIC may include a waveguide section evanescently coupled to a material platform exhibiting an electro-optic Pockels effect, enabling heterogeneous integration of electro-optic modulators. In another embodiment, the PIC may further include a waveguide section which is evanescently coupled to a material platform that exhibits strong nonlinearity, enabling heterogeneous integration of nonlinear waveguides. It is precisely this interplay of strong quadratic nonlinearity and optical gain which when combined with other integrated photonic components, may be configured, as described herein, to form circuits that perform functions exceeding the capability of the individual constituents.

Once the circuit is assembled, including a PIC with optical gain, it may be used by pumping the gain section, either optically or electrically. In certain embodiments, it may also be necessary to electrically drive the modulator contact(s) in the circuit to perform certain functions. Operating the circuit in this fashion results in an active photonic integrated (nonlinear) circuit, which may perform many functions depending on the arrangement of components. Finally, the circuit output is sent through an output waveguide which may then be coupled to free space, an optical fiber, or used as inputs to other PICs.

Example PICs that include integrated gain and nonlinear components are shown in the next sections which include short-pulse laser sources, tunable sources, ultrabroadband sources, and nonlinear dynamical photonic systems. These circuits can be used for applications ranging from communications to sensing and optical computing and quantum information processing.

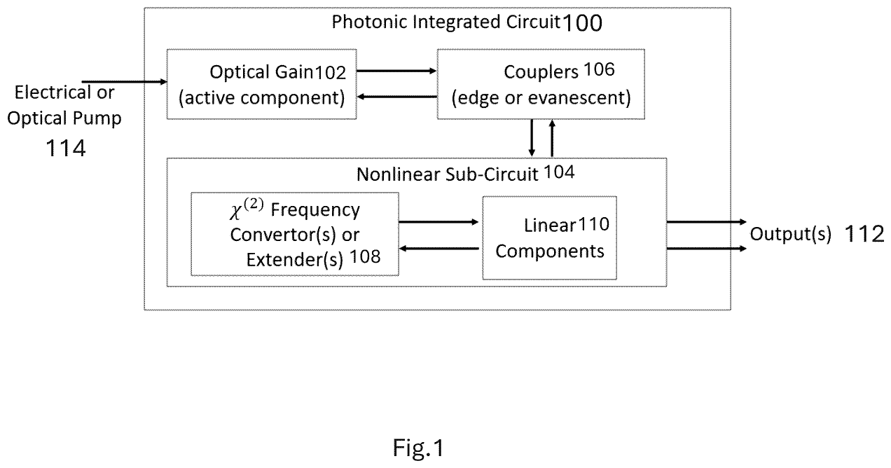

FIG. 1 illustrates a photonic integrated circuit 100 which includes an active component 102 providing optical gain for a wavelength range centered around a certain wavelength. This gain component is either optically or electrically pumped and can be in the form of a semiconductor optical amplified (SOA) or a rare-earth-doped material. The gain is coupled to a nonlinear sub-circuit 104 using couplers 106 either through one of the edges of the circuit or evanescently through the surface of the circuit. The nonlinear sub-circuit comprises at least one nonlinear component 108 with a second-order nonlinearity which provides frequency (wavelength) conversion and/or frequency extension (i.e. spectral broadening). This component can be in the form of a nonlinear waveguide, or a nonlinear resonator, or a combination of both. The nonlinear sub-circuit can further comprise other linear components 110, for instance mode filters and/or mode convertors for efficient coupling to the gain component, as well as waveguides, resonators, spectral filters, interferometers, actuators such as modulators, output couplers, etc. The circuit can be configured as a source of ultrashort pulses, frequency combs. or continuous-wave radiation, which can cover spectra outside the spectral coverage of the gain component. The nonlinear sub-circuit can also be configured to provide supercontinuum generation (SCG) as well as second harmonic generation to make a source of self-referenced frequency comb. The linear, nonlinear, and gain components of the circuit can be realized using hybrid integration, or heterogeneous integration of different material platforms. For instance the gain can be achieve in a III-V platform (such as GaAs, AlGaAs, or InP), the second-order nonlinearity can be achieved in a non-centrosymmetric material (such as lithium niobate, barium titanate, AlN, GaAs, etc.), and the linear components can be in the same platforms or additional material platforms such as Si or SiN.

### Circuit Examples

### Active Mode Locked Laser

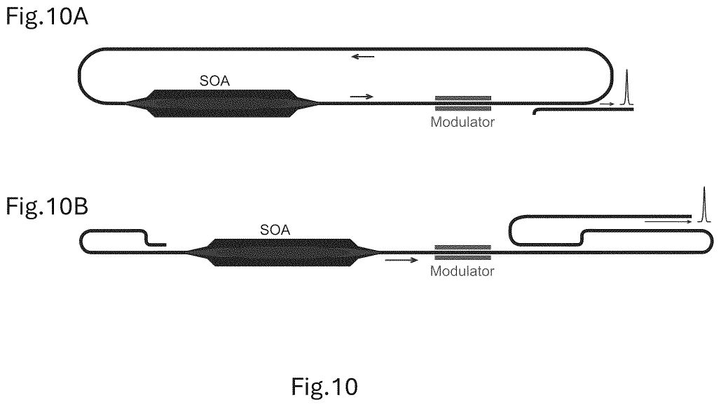

FIG. 10 shows two circuit designs for an integrated actively mode-locked laser. FIG. 10A shows a ring resonator that comprises the gain element that is evanescently coupled to the ring resonator, for instance a semiconductor optical amplifier (SOA). The ring resonator also includes an intracavity modulator, that can be a phase modulator, and intensity modulator, or both. The intracavity modulators are driven by radio frequency inputs at frequencies in the vicinity of the free-spectral range (FSR) of the resonator (or multiple integer of FSR for harmonic mode-locking). The driving of the modulator(s) can lead to mode-locking of the laser and producing short pulses that can be in the picosecond or femtosecond regime. The MLL also include couplers for the output, and potentially couplers for input for injection locking.

FIG. 10B shows an actively MLL with a linear cavity design. In this configuration the laser cavity is formed in between two reflective circuit components, for instance two loop mirrors on both sides of the circuit. The MLL further comprises a gain component, such as an SOA, intracavity modulator (intensity or phase) and output and input couplers.

### Nonlinear Switch Passive Mode-Locked Laser

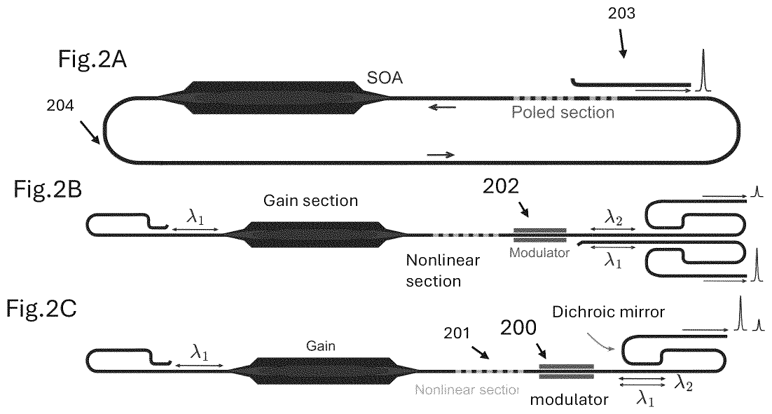

FIG. 2 shows a circuit design for an integrated passive mode-locked laser. It consists of a ring resonator 204 made up of two elements: a gain medium, and a mechanism to induce passive mode-locking. The gain medium can be implemented in the circuit via waveguide doping, or by evanescent coupling. In this example, the medium is an SOA. The poled section 201, together with a wavelength-dependent coupler 203, acts as an intensity-dependent coupler. Its transmission is low for low power and high for high power. This favors the generation of pulses that can be pico or femtosecond long. Several mechanisms are possible. In one embodiment, shown in FIG. 2A, the switch is obtained by introducing a defect into the poling [1] in a ring cavity configuration. Part of the intracavity signal leaks through the switch. In another embodiment, shown in FIG. 2B, a dichroic splitter separates the fundamental and second harmonic waves which are then each individually reflected by loop reflectors. In another embodiment, shown in FIG. 2C, a dichroic reflector is implemented.

### Nonlinear Optical Loop Mirror Passive Mode-Locked Laser

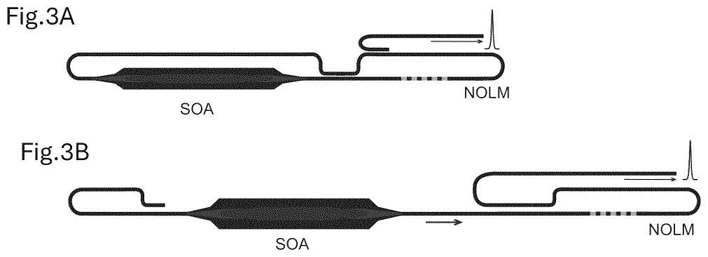

FIG. 3 shows two circuit designs for an integrated passive mode-locked laser in two different configurations, respectively called “figure-eight” (A) and “figure-nine” (B). As for any passive mode-locked laser, it requires at least two elements: a gain medium, and a passive mode-locking mechanism. The gain medium and its implementation have been described in FIGS. 1 and 2. Unless stated otherwise, in this figure and the next ones, the description of this part is identical. The main difference in this scheme lies in the passive mode-locking mechanism. Specifically, it consists of a Nonlinear Optical Loop Mirror (NOLM), i.e., a power-dependent mirror. It consists of a coupler closed on itself, leading to the propagation of a clockwise and a counterclockwise wave. Importantly, it includes an element that introduces an asymmetry. This asymmetry is, for instance, caused by a second-order nonlinear section that confers to both waves an additional phase but higher for the counterclockwise one. Since this phase depends on the power, the pulse solutions experience a higher reflectivity than the continuous ones. As a consequence, only the pulsed solution experiences gain in these schematics in an SOA. This naturally leads to the formation of short pulses, in the pico or femtosecond range depending on the design.

The difference between the “figure-eight” (A) and “figure-nine” (B) scheme is the feedback mechanism, either a ring cavity (A) or a linear cavity (B) with an additional (linear) mirror.

### Nonlinear Interferometer Passive Mode-Locked Laser

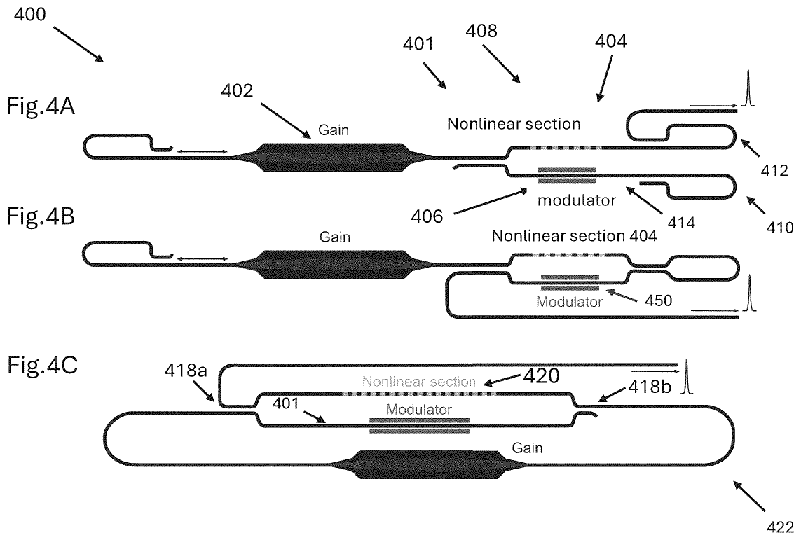

FIG. 4 shows several circuit designs for an integrated passive mode-locked laser 400. They consist of two elements: a gain medium 402, and a mechanism to induce passive mode-locking. The gain medium (e.g., having a peak gain at a first frequency) can be implemented in the circuit via waveguide doping, or by evanescent coupling. In this example, the medium is an SOA. The poled section 404, can be used to impart an intensity dependent phase accumulation on the light. This phase accumulation can be used to form an interferometer which acts as part of the mode-locking mechanism. In the embodiments shown in FIG. 4, Periodically Poled Lithium Niobate (PPLN) (or other periodically poled or spatially patterned nonlinear material) is placed in one arm of the interferometer, and a modulator 406 is placed in the other arm of the interferometer. FIG. 4A shows one embodiment of the nonlinear Michelson interferometer 401 mode-locked laser in a linear cavity. The interferometer comprises a two-by-two coupler 408 comprising coupler ports 410 wherein two of the coupler ports are terminated by mirrors 412, such as partial or almost perfect loop mirrors or Bragg reflectors, and at least one of the arms 414 of the interferometer comprises the waveguide 404 comprising a waveguide section with the second order (quadratic) nonlinearity configured to provide phase matched or phase mismatched second-harmonic generation in the vicinity of the first frequency.

Another embodiment, shown in in FIG. 4B, is formed by a Mach-Zehnder interferometer 407 in a linear cavity. Another embodiment, shown in FIG. 4C, is formed by a Mach-Zehnder interferometer in a ring cavity. FIGS. 4B and 4C illustrate the non-linear circuit 104 comprising a Mach-Zehnder interferometer comprising two two-by-two couplers 418a, 418b which are connected to each other in series via connecting waveguide 420 and one of the connecting waveguides includes the waveguide 420 comprising a nonlinear waveguide section with the second order (quadratic) nonlinearity configured to provide phase matched or phase mismatched second-harmonic generation in the vicinity of the first frequency.

### Nonlinear Amplifying Loop Mirror Passive Mode-Locked Laser

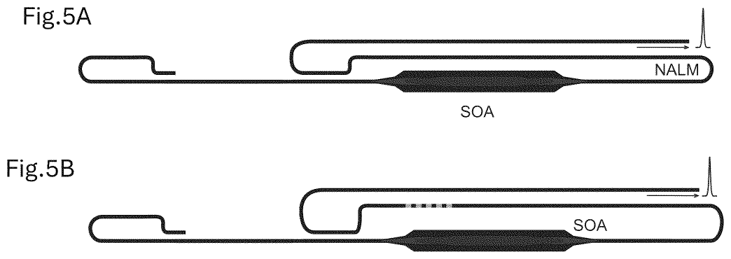

FIG. 5 shows a circuit design for an integrated passive mode-locked laser in two different and “figure-nine” configurations. While in FIG. 3, the mechanism that provides the passive mode-locking is a NOLM, it is here provided by a Nonlinear Amplifying Loop Mirror (NALM). Similarly to the NOLM, it consists of a coupler closed on itself with an element that introduces an asymmetry. In this case, a gain medium. In this specific example, the gain medium is an SOA. The gain medium allows the counterclockwise wave to acquire a larger nonlinear phase than the clockwise wave, leading to the asymmetry required to introduce a power-dependent reflectivity. This nonlinear phase can either be acquired through third-order nonlinear effects (A) or through second-order nonlinear effects (B). The “figure-eight” configuration, although not represented here, is also possible (see, e.g., FIG. 3).

### Mamyshev Oscillator

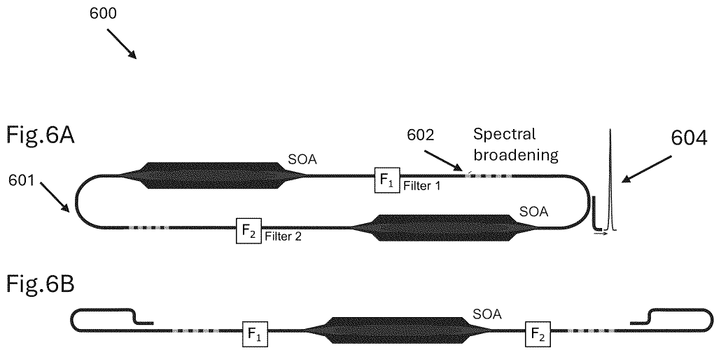

FIG. 6 shows a circuit design for an integrated Mamyshev laser 600 in a ring (A) and in a linear (B) configuration. A couple of filters F1, F2 and amplifiers SOA allow for femtosecond, high-energy pulse 604 formation. The principle is as follows, for the ring configuration (A). A first filter, narrow with respect to the pulse's largest spectral density, removes an important fraction of the pulse energy. After this spectral narrowing, the pulse is amplified in a gain medium SOA. If the filtered-pulse peak power is high enough, the pulse will experience a significant spectral broadening in a nonlinear section 602 (here, a second-order nonlinear section). A second filter, spectrally shifted from the first but still overlapping with the latter, is then used. A second amplifier allows the cycle to perpetuate. This specific configuration favors short pulse formation with high peak power. The resonator 601 can also include other elements (e.g., modulators, etc) to initiate the oscillation. An output coupler allows extracting part of the intracavity power.

In the linear configuration (B), owing to the double-pass in the gain medium, there is no need for a second amplifier to perpetuate the cycle. In this case, both sides of the resonators end with a mirror to introduce the feedback required for the oscillation.

Thus, FIG. 6 illustrates an embodiment wherein the nonlinear sub-circuit comprises the at least one nonlinear component comprising at least two spectral broadening sections 602 and two filters F1, F2 and is configured as a Mamyshev oscillator to generate short pulses 604.

### Parametrically Driven Cavity Soliton

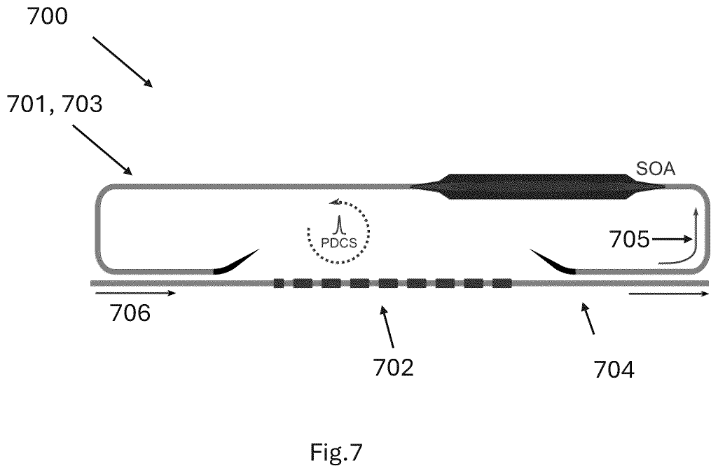

FIG. 7 depicts an integrated Degenerate Optical Parametric Oscillator (OPO) 700. The resonator 703 is designed to be resonant at half the pump frequency. For that purpose, the pump frequency must be down-converted by means of a nonlinear section 702, here a periodically poled second-order material. Once the half-frequency generated, it is coupled in the cavity using a wavelength-selective coupler 704. Here, the coupler is design to not couple the pump frequency into the resonator. Other configurations with pump coupling can also be envisioned. After one roundtrip, the light propagating into the cavity is coupled into the poled section thanks to another wavelength-selective coupler. In practice, the OPO starts oscillating when the gain at half the pump frequency (proportional to the pump power) is higher than the roundtrip loss. To lower the pump power requirement while allowing for an important output coupling, the cavity includes an amplifier whose gain is set slightly below the roundtrip losses. This allows working with low (effective) loss. If the pump frequency is well chosen, this resonator can lead to the formation of short pulses (parametrically driven cavity soliton, PDCS), hence forming a pulse train. This can be seen as another mode-locking scheme that does not require any additional intracavity component. The pulse formation is not limited to PDCSs. Among others, the resonator can host simultons, walk-off induced solitons, or effective Kerr cavity soliton, for example. Intracavity modulators can also be added, for instance to induce mode-locking. While FIG. 7 focuses on the degenerate emission with a non-resonant pump, other configurations are possible (pump resonant, nondegenerate configuration, etc.).

### Pump Enhanced OPO

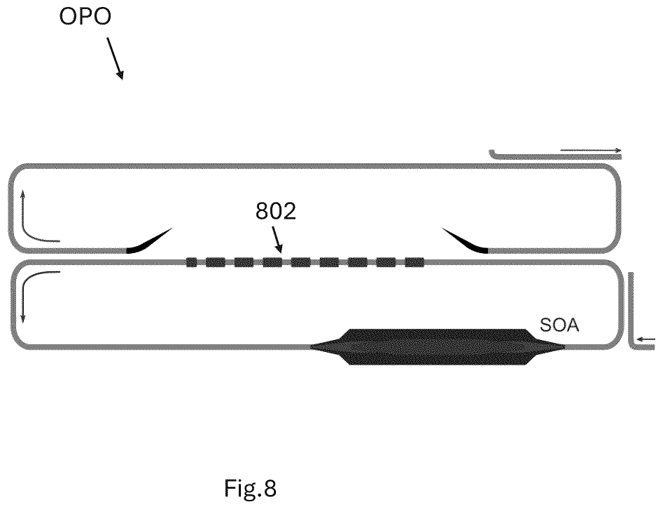

FIG. 8 depicts an integrated Degenerate Optical Parametric Oscillator (OPO) embedded in a laser cavity. The OPO ring cavity is located at the top. It is very similar to the one described in FIG. 7. The difference here lies in the fact that the OPO is not pumped by an external pump but by being directly embedded in a laser cavity (bottom). The laser cavity includes an amplifier and is resonant at twice the OPO resonant frequency. It includes a poled section 802, required to convert part of the laser field to the pump half-frequency, which is the OPO resonant frequency. The laser can be either continuous or pulsed, and several intracavity components can be added inside the cavity (filters, modulators, couplers, etc). In addition, the device can work in a nondegenerate configuration.

### Frequency Generation (Cascaded Amplifying and Spectral Broadening for Example)

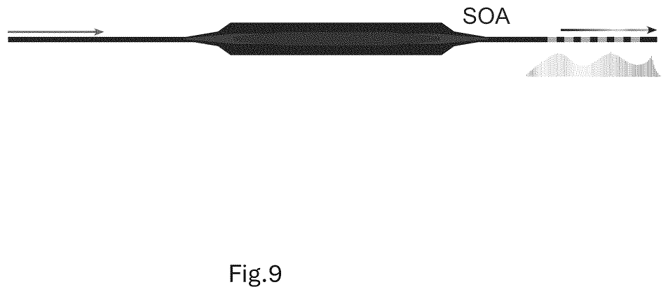

FIG. 9 depicts a frequency generation device. It consist of two elements: a gain medium, and a mechanism to induce the formation of a new frequency. The gain medium can be implemented in the circuit via waveguide doping, or by evanescent coupling. In this example, the medium is an SOA and PPLN is used as the frequency generation device. Another embodiment further includes several cascaded components (such as filters, modulators, and couplers) which can be used to perform functions such as: multiplexing/demultiplexing the new frequencies; amplitude and/or phase modulation to synthesize various spectral and temporal shapes.

### Frequency Generation (Cascaded AMLL and Pulse Compression (Spectral Broadening), for Example)

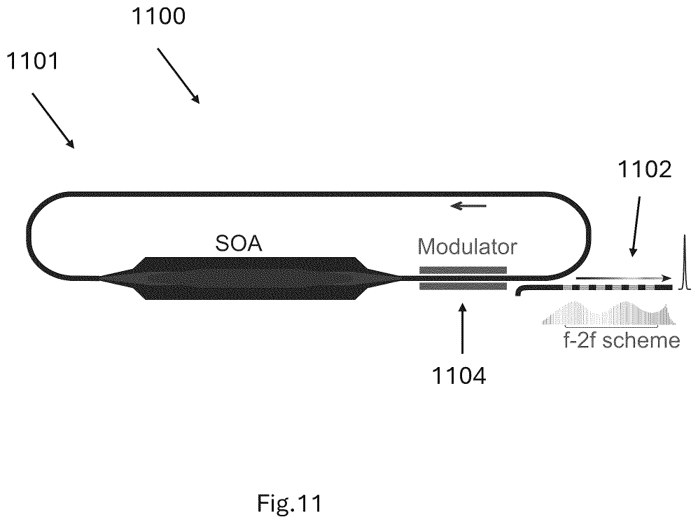

FIG. 11 depicts a pulse-driven frequency generation device 1100. This embodiment consists of a pulse generator cascaded by a frequency generation device. In this example, the pulse generator is formed by the ring cavity actively mode-locked laser of FIG. 1a. In other embodiments, this pulse generator may be any of the mode-locked lasers listed herein. In this embodiment, PPLN 1102 is used as the frequency generation device. Another embodiment further includes several cascaded components (such as filters, modulators, and couplers) which can be used to perform functions such as: multiplexing/demultiplexing the new frequencies; amplitude and/or phase modulation to synthesize various spectral and temporal shapes.

### Butt-Coupling Configuration

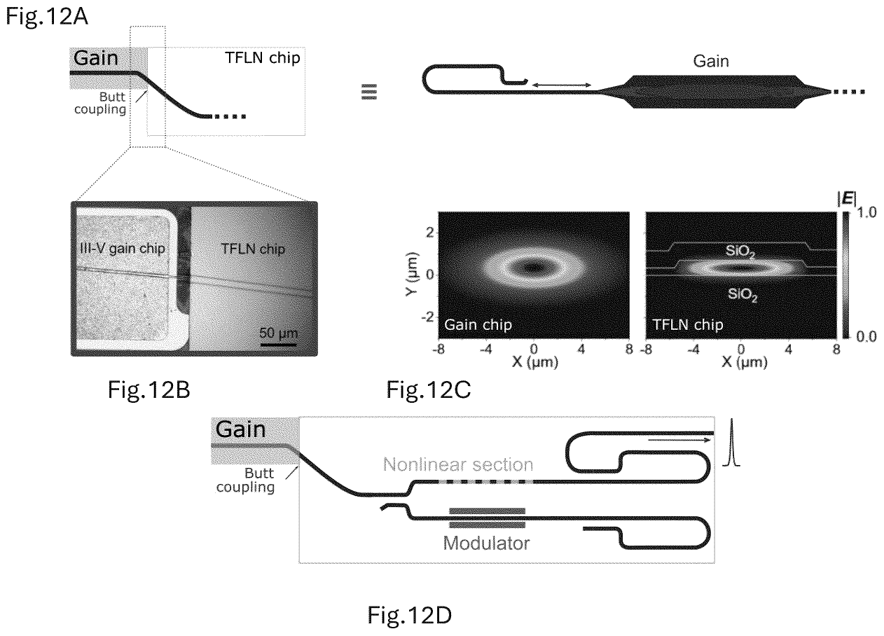

Another configuration can be envisaged to provide the PIC with gain. Instead of having the gain directly on the PIC, it's possible to couple one side of the chip to a gain medium, such as a single-angle facet (SAF) gain chip. This reflective configuration is illustrated in FIG. 12A. The first pass through an on-chip gain medium followed by reflection to allow a second pass through the gain medium is similar to butt-coupling a gain medium at one end of the chip. In this linear configuration, a tap on the nonlinear PIC can facilitate coupling with the gain chip. As an illustration, FIG. 12B is the butt-coupling configuration equivalent to FIG. 4A [passive mode-locked laser with a linear cavity nonlinear Michelson interferometer].

### Working Example: Passively Mode-Locked Laser

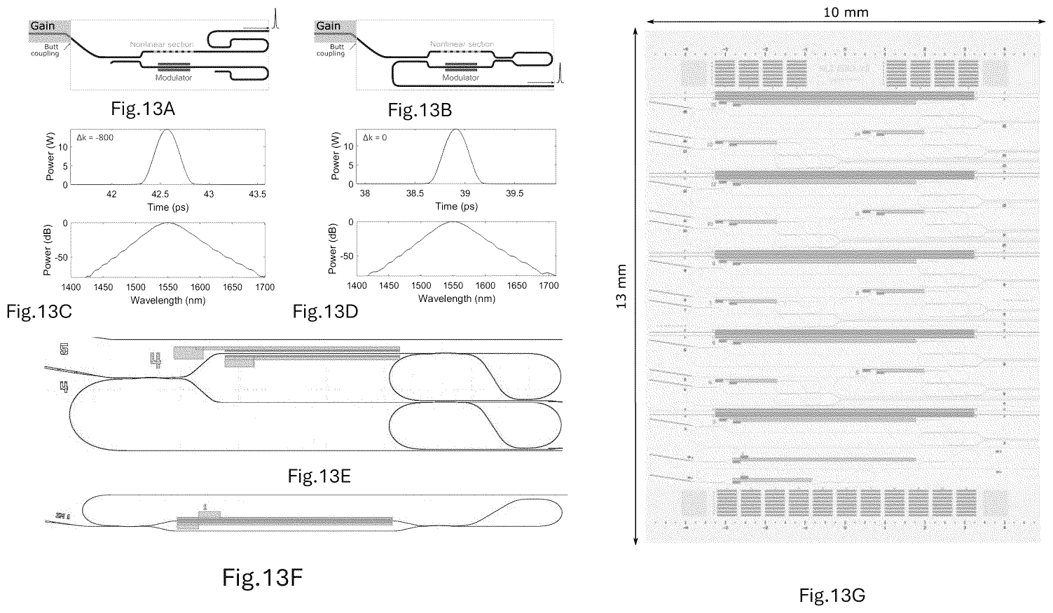

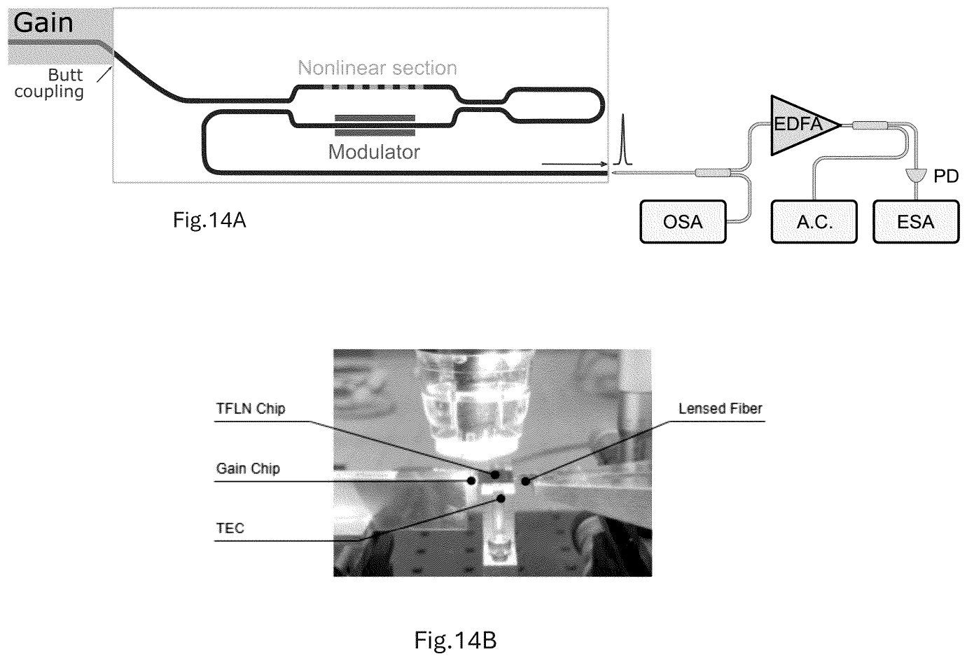

An image of a passively mode-locked laser chip in the configuration depicted in FIG. 12B is shown in FIG. 13. The chip, made of thin-film lithium niobate, is 10×13 mm² and consists of 17 mode-locked lasers with different poling periods [see FIG. 13A]. A single laser is approximately 8 mm long and 0.75 mm wide. We studied two different mode-locking configurations: 2 Mach Zehnder Interferometers (MZIs) [see FIG. 4B and FIG. 14C] and 15 Michelson Interferometers [see FIG. 4A and FIG. 14B]. The chip temperature is controlled using a Thermo-electric Cooler (TEC). Regardless of the configuration, the mode-locking regime can only be reached close to phase-matching, the chip temperature is controlled using a TEC, set to approximatively 18 deg C. The left-hand side of the chip is butt-coupled to a commercial semiconductor optical amplifier (SOA, electrically driven) that provides the optical gain [see FIG. 12A]. We designed a taper to mitigate the coupling loss between the laser chip and the SOA. The gain chip has a highly reflective facet that allows the linear cavity configuration. The light at the output of the laser (right) is collected using a lensed fiber to carry out spectral and temporal characterizations. FIG. 14 illustrates erbium doped fiber amplifier EDFA, optical spectrum analyzer (OSA), spectrum analyzer (ESA), and A.C

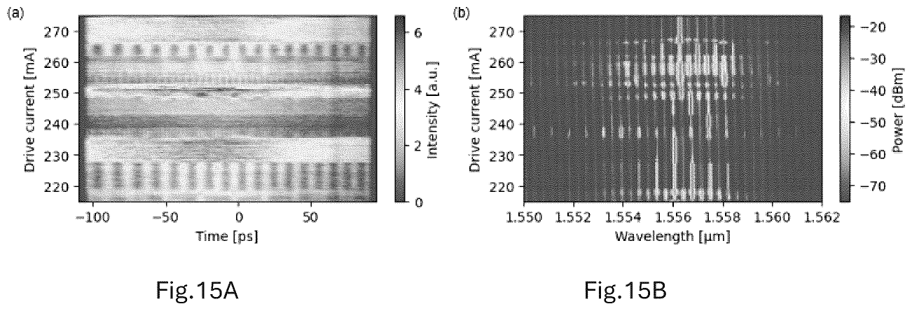

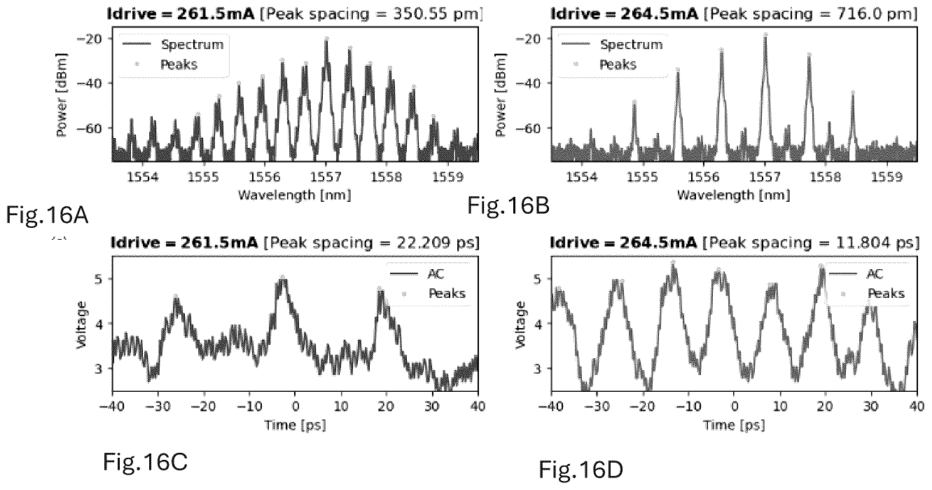

FIG. 15 shows the autocorrelation (A) and the spectrum (B) of the laser as the SOA drive current is swept from 215 mA to 275 mA. The autocorrelation shows clear temporal features, as shown in FIG. 16A, whose spacing matches the free spectral range of the strongest lasing peaks, shown in FIG. 16B. Furthermore, as the drive current of the SOA is swept, the laser cycled between multiple states. Specifically, two predominant states emerged from the laser, as shown in FIG. 15A. The first, shown in FIG. 16A, contains a denser spectrum, with a roughly 351 pm spacing between emission peaks, accompanied by an autocorrelation trace, shown in FIG. 16C, with a 22.2 ps spacing between temporal peaks, which translates to a 45.02 GHz repetition rate. The second state that emerges is a comparatively sparser spectrum, shown in FIG. 16b, with an emission peak separation of 716 pm and a repetition rate of 11.8 ps or 84.74 GHz, shown in FIG. 16d.

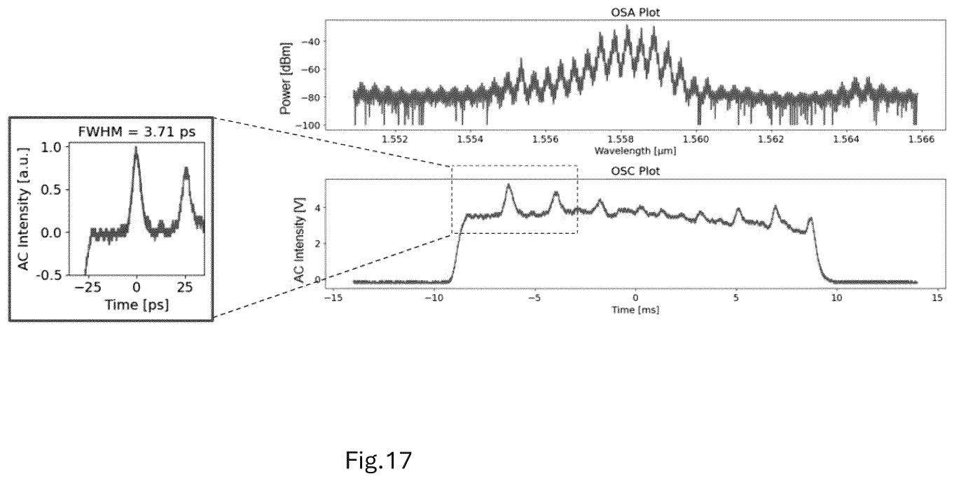

Finally, a dense comb spectrum achieves a pulse width of 3.71 ps, as shown in FIG. 17. Thus, this active photonic integrated nonlinear circuit accomplishes, in one embodiment, passive mode-locking using the methods described herein. These results demonstrate a clear

### Cascaded AMLL and Pulse Compression (Spectral Broadening)

### Example Components

### Curved Directional Couplers

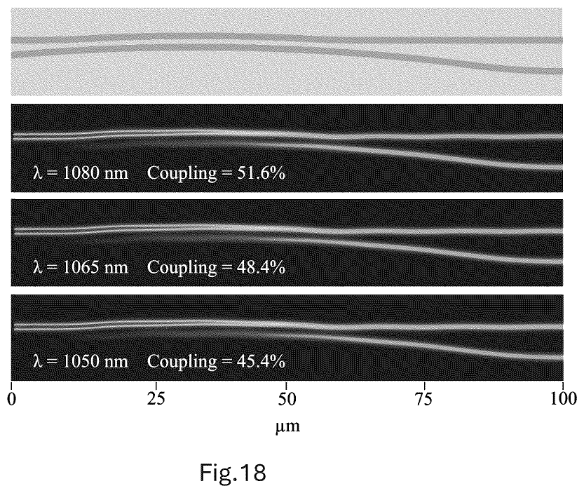

Curved directional couplers (CDC) reduce the wavelength dependence of coupler length. CDCs are useful for broadband 3 dB couplers which are particularly necessary for broadband on-chip reflectors. CDCs are one of many coupler topologies which exhibit specific spectral responses. FDTD simulations show CDCs can maintain near 50% splitting across a 30 nm bandwidth, as shown in FIG. 18.

Sagnac Loop Reflector (Loop mirror)

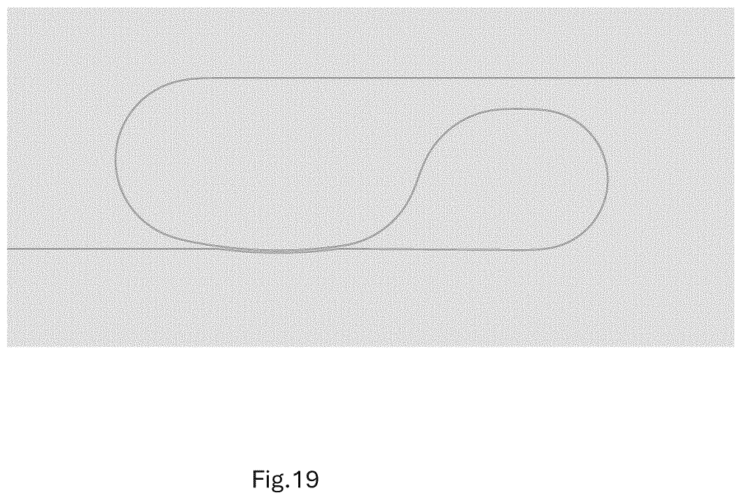

A reflecting component may be formed by connecting 4-port couplers output ports together. The wavelengths which experience 50% power coupling will be reflected entirely back through the input port due to constructive interference. Therefore, a single coupler may be used to implement a reflective component on chip. FIG. 19 shows an example layout of such a loop mirror.

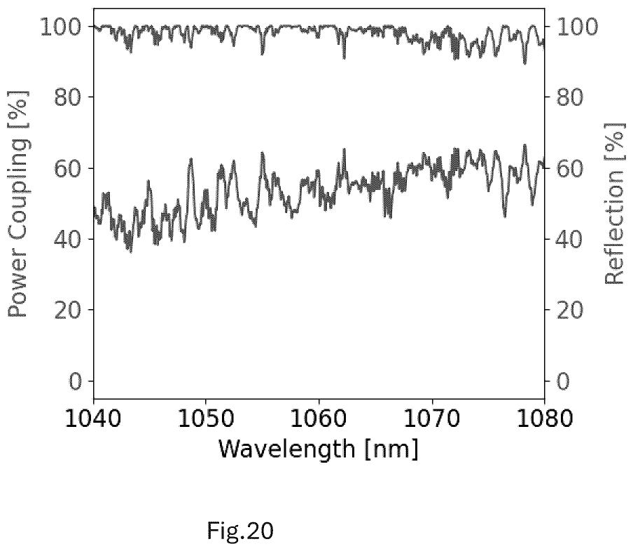

A CDC was fabricated to have 3 dB coupling near 1060 nm. This CDC had a top width of 1 μm, a 500 nm coupler gap, a radius of curvature of 500 μm and a length of 32.7 μm. Broadband measurements show roughly 50% power coupling across a 40 nm bandwidth. Employing this coupler in a loop mirror configuration would produce >90% reflection across the 40 nm bandwidth (FIG. 20).

### Periodically Poled Lithium Niobate

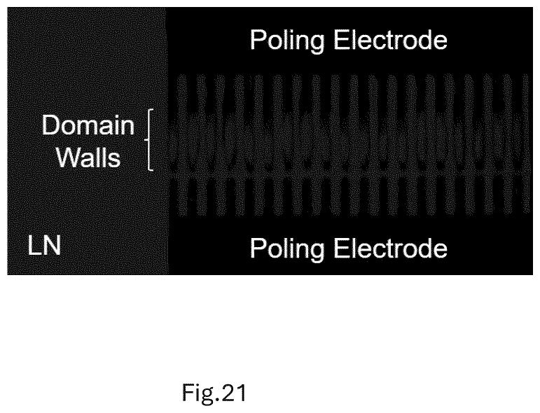

Lithium niobate exhibits a strong second order nonlinearity which can be used to generate new frequencies. This frequency conversion can be made efficient if a phase matching condition between the respective frequencies are met. Quasi phase matching can be used to achieve efficiency nonlinear conversion on thin film lithium niobate. FIG. 21 shows a two-photon absorption microscope image of a periodically poled lithium niobate wafer. This technique has been used on TFLN to demonstrate broadband phase-sensitive amplification of over 50 dB/cm [2]. Furthermore, periodically poled lithium niobate can be designed with a slight phase-mismatch at designated frequencies, resulting in an intensity dependent phase accumulation due to back and forth conversion between two frequencies. Such a device can be used as an effective-Kerr nonlinear waveguide [citation] or for pulse compression [9].

### Electro-Optic Phase Modulator

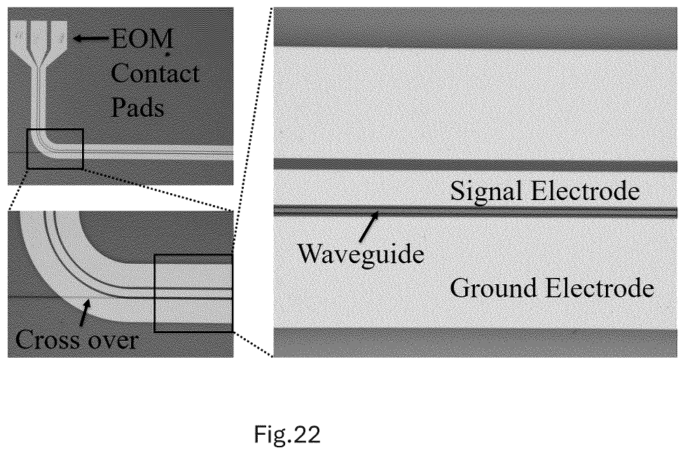

Lithium niobate exhibits a strong Pockel's effect with an r₃₃ electro-optic coefficient of 31 pm/V. Utilizing x-cut Thin Film Lithium Niobate (TFLN), electro-optic modulators may be implemented by placing electrodes on either side along a waveguide such that the electric field generated by a potential difference across the electrodes aligns with the extraordinary axis of the crystal at the point of the waveguide. By placing the electrodes on top of the a cladding material such as SiO2 [3] the propagation loss caused by the electrodes is minimized. This has two advantages, the electrodes can cross over the waveguide structures with minimal loss, allowing easy routing to conveniently places probe pads and the electrodes may be brought very close together on either side of the waveguide, reducing the halfwave voltage and improving modulator efficiency. This style of EOM, shown in FIG. 22, has been used to create an actively mode-locked laser on thin film lithium niobate [4].

### Integrated Gain Component Through Evanescent Coupling

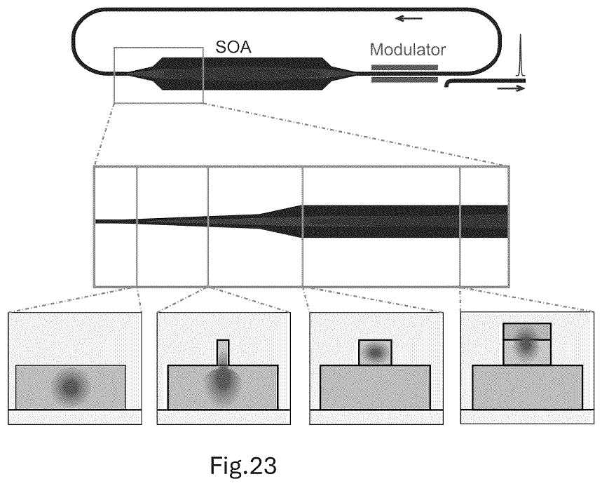

The coupling to the integrated gain component can be designed through evanescent coupling of a waveguide section of the PIC. In one example, a waveguide section in the PIC in the integrated circuit can couple light into the gain component, and after a propagation length in the gain element, the light can couple back to a waveguide section on the PIC. An example of such a back-and-forth evanescent coupling components in LN waveguide to an SOA gain component is shown in FIG. 23. An inverse taper structure may be implemented to convert the mode from the LN to the gain structure, using an intermediate layer of crystalline Silicon to improve coupling [5]. In this way, the mode of the EM field is pulled up into the gain structure, amplified, then pushed back down into the LN waveguiding layer.

Another example of integrating gain in the nonlinear PIC is through evanescent coupling of a waveguide section without transferring most of the light into a different component. An example of such a gain component is through the evanescent tail of the light mode propagating in the PIC experiencing gain, for instance through doped material and optical pumping on top of the PIC waveguide [6], and or with other similar hybrid or heterogeneous integration schemes [7]

### Spatial Mode Filters and Converters

The circuit can further include converters and filters for spatial modes. This is mostly because different components in the circuit can benefit from different spatial modes. For example, the couplers and/or gain components can be optimized for spatial modes that are different from those in the nonlinear waveguide sections. One example is to achieve a desired dispersion property in a waveguide section of the PIC, for instance for optimum OPA [2], mode-locking element [4], and/or spectral broadening [8]. Another example is for efficient input and/or output coupling from/to free space and/or optical fiber.

### Process Steps

FIG. 1 also illustrates a method of fabricating the Active Photonic Integrated Nonlinear Circuits (APINCs) described herein involving integrating an active medium including optical gain with a nonlinear subcircuit comprising at least one nonlinear component comprising second-order nonlinearity. The APINC further comprises at least one waveguide each having a width and height of less than 5 micrometers. Example materials exhibiting second-order nonlinearity include but are not limited to, lithium niobate, lithium tantalate, potassium titanyl phosphate, aluminum nitride, gallium arsenide, indium phosphide, aluminum gallium arsenide, GaP, or InGaP. The linear portion of the nonlinear sub-circuit may further be comprised of the nonlinear material or some other material platform capable of photonic integration. In some examples, the nonlinear component may be heterogeneously integrated with the subcircuit's linear portion comprising a different material platform (e.g. bonding or micro-transfer printing [11]). In some examples, hybrid integration of the nonlinear component with subcircuit's linear portion comprising a different material platform is used (e.g. SiN on LN strip-loaded waveguides). In some examples, the nonlinear component may be monolithically integrated with the subcircuit's linear portion (e.g. lithium niobate on silicon dioxide with patterned lithium niobate waveguides). In some examples, a combination of heterogeneous, hybrid, and monolithic techniques is used.

The nonlinear materials may be phase-matched and dispersion-engineered to design the second-order nonlinear response, group velocity mismatch (GVM), and group velocity dispersion (GVD) of the nonlinear portion of the subcircuit [12]. The linear portion of the sub-circuit may further be dispersion-engineered to design its group velocity mismatch (GVM), and group velocity dispersion (GVD).

The nonlinear subcircuit is then coupled to the active component including optical gain. In some examples, the optical gain is heterogeneously integrated with the material platform(s) (e.g. microtransfer printing of semiconductor optical amplifiers [13, 14], bonding, direct epitaxial growth of III-V layers on a material platform using a buffer layer, or some combination thereof [15]). In some examples, hybrid integration of the optical gain with the material platform(s) is used (e.g. butt-coupling of an SOA). In some examples, the optical gain is monolithically integrated with the material platform(s) (e.g. rare-earth doping optically pumped waveguides [16])

In one embodiment, the circuit is fabricated using a commercial wafer with an x-cut, thin-film MgO-doped lithium niobate layer and a silicon oxide buffer layer. The nonlinear component is implemented via quasi-phase matching through periodic polling. The waveguides are patterned by e-beam lithography and dry etched with Ar+ plasma to a depth less than that of the thin-film thickness, forming ridge waveguides. A portion of the waveguide implements a mode-matching taper to facilitate evanescent coupling to a microtransfer printed III-V gain section.

Quasi-phase matching of the nonlinear waveguides can be selected for a variety of nonlinear processes. The poling enables phase matching for some frequency components but not others, and the target frequency components can be engineered for example via chirped poling. The pulses can be chirped in the nonlinear waveguide prior to amplification in the waveguide and then de-chirped after amplification.

Actuators 406 (e.g., electro-optic modulator, an electric heater, a thermo-optical heater, or a piezoelectric transducer, e.g., to modulate phase or amplitude of waves or refractive index of the using electric field or temperature) can be fabricated by depositing metallization (e.g., electrodes 450 for applying bias as illustrated in FIG. 4) coupled to the waveguides 401 formed in the chip.

The device/photonic integrated circuit can be embodied in many ways including, but not limited to, the following (referring also to FIGS. 1-23)
1. A photonic integrated circuit 100 (e.g., as illustrated in FIG. 1), comprising
   at least one gain section 102 (e.g., integrated optical gain section or optical gain section) having a peak gain at a first frequency and
   at least one nonlinear sub-circuit 104 which is coupled to the gain section either evanescently or through edge coupling, wherein the nonlinear sub-circuit further comprises:
   at least one nonlinear component 108 comprising at least one of a waveguide 201, 401 or a resonator 210, 703, 422, 601 comprising second-order nonlinearity enabling generation of frequency components at least one octave (e.g., factor of 2) below or above the first frequency, and the nonlinear sub-circuit is configured to provide one or a combination of the functions:
   nonlinear interferometry, wherein the non-linear sub-circuit comprises an interferometer 401, 407 having an interferometer output 112 that depends on the input 114 intensity to the nonlinear sub-circuit,
   spectral broadening by extending the spectrum of the electromagnetic wave(s) generated in the non-linear sub-circuit or output of the non-linear subs-circuit outside the gain spectrum of the gain section.
2. The circuit of clause 1, wherein the optical gain section comprises a semiconductor optical amplifier (SOA) which is electrically pumped.
3. The circuit of clause 1, wherein the optical gain section comprises a rare-earth doped material which is optically pumped.
4. The circuit of any of the clauses 1-3, wherein the nonlinear sub-circuit comprises the non-linear component comprising a section configured to provide phase matching or a certain or predetermined level of phase mismatch for one or a plurality of second order (e.g., quadratic) nonlinear process such as second-harmonic generation, difference-frequency generation, sum-frequency generation, or optical parametric amplification.
5. The circuit of any of the clauses 1-4, wherein the nonlinear component comprises a section made of a ferroelectric material, such as lithium niobate or lithium tantalate or barium titanate, and the phase matching is provided by periodic or aperiodic poling of the ferroelectric domains of the ferroelectric material.
6. The circuit of any of the clauses 1-5, wherein the nonlinear sub-circuit comprises the interferometer 401 comprising a Michelson interferometer (e.g., as shown in FIG. 4A) comprising
   a two-by-two coupler comprising coupler ports wherein two of the coupler ports are terminated by mirrors, such as partial or almost perfect loop mirrors or Bragg reflectors, and at least one of the arms of the interferometer comprises the waveguide comprising a waveguide section with the second order (quadratic) nonlinearity configured to provide phase matched or phase mismatched second-harmonic generation in the vicinity of the first frequency.
7. The circuit of any of the clauses 1-6, wherein the nonlinear subcircuit comprises the interferometer 407 comprising a Mach-Zehnder interferometer (e.g., as shown in FIGS. 4B and 4C) comprising:
   two two-by-two couplers which are connected to each other in series via one or more connecting waveguides, and at least one of the connecting waveguides includes the waveguide comprising a waveguide section with the second order (quadratic) nonlinearity configured to provide phase matched or phase mismatched second-harmonic generation in the vicinity of the first frequency.
8. The circuit of clause 7, wherein the Mach-Zehnder nonlinear interferometer is terminated by a partial or almost perfect loop mirror or other types of reflectors, as illustrated in FIG. 4B.
9. The circuit of clause 7, wherein the Mach-Zehnder nonlinear interferometer is placed inside a laser resonator 422 configured as a ring or linear resonator comprising the optical gain section or element, as illustrated in FIG. 4C.
10. The circuit of any of the clauses 1-5, wherein the nonlinear sub-circuit contains or comprises the nonlinear component (waveguide 602) comprising at least two spectral broadening sections and two filters F1, F2 and is configured as a Mamyshev oscillator to generate short pulses 604, e.g., as illustrated in FIG. 6.
11. The circuit of any of the clauses 1-10, wherein nonlinear sub-circuit further comprises an actuator, in the form of an electro-optic or thermo-optic or piezoelectric modulator.
12. The circuit of clause 11, wherein the actuator is an electrooptic modulator which is configured to be driven at frequencies from DC to 10's of GHz or a portion of this range.
13. The circuit of any of the clauses 1-5 or 11-12 wherein the nonlinear sub-circuit comprises an optical parametric oscillator, e.g., as illustrated in FIG. 8.
14. The circuit of any of the clauses 1-13, further comprising at least one coupler for coupling to the resonator and/or the waveguide, the photonic integrated circuit further comprising at least one mode converter 110 and at least one spatial filter 110 coupled to match the spatial modes of electromagnetic pulses between the coupler 106, the gain section 102, and the nonlinear component comprising the waveguide 108.
15. The circuit of any of the clauses 1-14, wherein the one or a plurality of waveguides in the nonlinear sub-circuit are dispersion-engineered for specific group velocity dispersions and/or group velocity mismatch among different spectral contents of electromagnetic waves generated in the non-linear sub-circuit to enable formation of electromagnetic pulses shorter than 100 picoseconds (ps) in the circuit or spectra of the electromagnetic waves spanning beyond an octave.
16. The circuit of any of the clauses 1-15, wherein the nonlinear sub-circuit is configured to create a passively mode-locked laser generating electromagnetic pulses shorter than 20 picoseconds (ps).
17. The circuit of any of the clauses 1-5 or 11-16 wherein the nonlinear sub-circuit is configured to create an electro-optic frequency comb source 1100 wherein the source comprises a laser cavity 1101 comprising the gain element/section (e.g., SOA) and one or a plurality of electro-optic modulators 1104 in the nonlinear sub-circuit (e.g., FIG. 11).
18. The circuit of any of the clauses 1-17 wherein the spectral broadening is covering one octave or ⅔ of an octave, and the circuit is further configured to provide a self-referenced frequency comb through f-2f or 2f-3f interferometry (e.g., FIG. 11).
19. The circuit of any of the clauses 1-18 (e.g., as illustrated in FIG. 7) wherein the non-linear sub-circuit comprises the resonator comprising the parametrically driven active cavity 701 comprising a coupler 704 comprising wavelength selective coupler coupling the optical gain section (e.g., SOA) to the nonlinear waveguide 702 configured to generate a half frequency of a pump, wherein the optical gain region/section is configured to amplify the half frequency and the coupler is designed to transmit the half frequency 705 but not the pump 706 inputted to the non-linear sub-circuit.
20. The circuit of any of the clauses 1-19, wherein the nonlinear sub-circuit is configured to support formation of solitons.
21. The circuit of any of the clauses 1-20 wherein the waveguides each having a width and height of less than 5 micrometers.
22. The circuit of any of the clauses 1-21, wherein the waveguide 401 can comprise nonlinear periodically poled sections 420.

### Further Device Embodiments

A photonic integrated circuit comprising one or a plurality of waveguides, couplers, spectral filters, spatial filters, mode converters, resonators, modulators, nonlinear waveguides, and a waveguide section with an integrated optical gain. The latter can be achieved by evanescent or butt-coupling.

The circuit where the components are implemented on a material platform with second-order nonlinearity.

The circuit where a waveguide is evanescently coupled to a material platform with second-order nonlinearity.

The circuit where the nonlinear waveguides are periodically poled to phase match nonlinear processes including SHG, DFG, SFG, OPA, etc.

The circuit where the nonlinear waveguides are periodically poled with a phase-mismatch to induce a nonlinear phase shift.

The circuit where the optical gain is provided by a semiconductor optical amplifier coupled to the waveguide section.

The circuit where the active gain medium is rare-earth-doped material coupled to the waveguide section.

The circuit where the modulators are electro-optic modulators.

The circuit where the modulators are achieved through thermal, piezo, or carrier injection effects.

The circuit where the couplers are designed to be spectrally selective.

### Example Functionalities

The circuit where the components are configured to create:
An actively mode-locked laser based on intracavity phase modulation,
An actively mode-locked laser based on intracavity amplitude modulation,
A passively mode-locked laser based on a nonlinear mirror saturable absorber,
A passively mode-locked laser based on a nonlinear interferometer,
A passively mode-locked laser based on a nonlinear optical loop mirror,
A passively mode-locked laser based on a nonlinear amplifying loop mirror,
A Mamyshev oscillator,
A pulsed laser as well as additional components for spectral broadening and/or f-2f interferometry to yield a self-references or tunable broadband frequency comb,
An active cavity,
A driven active cavity,
A parametrically driven active cavity,
An optical parametric oscillator with integrated pump laser,
A singly resonant optical parametric oscillator,
A double resonant optical parametric oscillator,
A triply resonant optical parametric oscillator,
A pump-enhanced singly resonant optical parametric oscillator,
A pump-enhanced doubly resonant optical parametric oscillator,
An integrated laser with nonlinear frequency conversion components,
An electro-optic frequency comb source.

A photonic integrated circuit comprising
one or more resonators coupled to one or more nonlinear periodically poled waveguides, one or more optical gain sections, and one or more couplers mode matched, positioned, and configured to introduce asymmetry in a nonlinear phase of different frequency components of electromagnetic pulses propagating in the resonator, the asymmetry depending on an intensity of the different frequency components.

### REFERENCES

The following references are incorporated by reference herein
[1] Guo, Qiushi, Ryoto Sekine, Luis Ledezma, Rajveer Nehra, Devin J. Dean, Arkadev Roy, Robert M. Gray, Saman Jahani, and Alireza Marandi. “Femtojoule Femtosecond All-Optical Switching in Lithium Niobate Nanophotonics.” Nature Photonics, Jul. 28, 2022. https://doi.org/10.1038/s41566-022-01044-5.
[2] Ledezma, Luis, Ryoto Sekine, Qiushi Guo, Rajveer Nehra, Saman Jahani, and Alireza Marandi. “Intense Optical Parametric Amplification in Dispersion-Engineered Nanophotonic Lithium Niobate Waveguides.” Optica 9, no. 3 (Mar. 20, 2022): 303.
   https://doi.org/10.1364/OPTICA.442332.
[3] Jin, Mingwei, Jiayang Chen, Yongmeng Sua, Prajnesh Kumar, and Yuping Huang. “Efficient Electro-Optical Modulation on Thin-Film Lithium Niobate.” Optics Letters 46, no. 8 (Apr. 15, 2021): 1884. https://doi.org/10.1364/OL.419597.
[4] Guo, Qiushi, Benjamin K. Gutierrez, Ryoto Sekine, Robert M. Gray, James A. Williams, Luis Ledezma, Luis Costa, et al. “Ultrafast Mode-Locked Laser in Nanophotonic Lithium Niobate.” Science 382, no. 6671 (Nov. 10, 2023): 708-13. https://doi.org/10.1126/science.adj5438.
[5] Op De Beeck, Camiel, Felix M. Mayor, Stijn Cuyvers, Stijn Poelman, Jason F. Herrmann, Okan Atalar, Timothy P. McKenna, et al. “III/V-on-Lithium Niobate Amplifiers and Lasers.” Optica 8, no. 10 (Oct. 20, 2021): 1288. https://doi.org/10.1364/OPTICA.438620.
[6] Rönn, John, Weiwei Zhang, Anton Autere, Xavier Leroux, Lasse Pakarinen, Carlos Alonso-Ramos, Antti Säynätjoki, et al. “Ultra-High on-Chip Optical Gain in Erbium-Based Hybrid Slot Waveguides.” Nature Communications 10, no. 1 (Jan. 25, 2019): 432.
   https://doi.org/10.1038/s41467-019-08369-w.
[7] Kaur, Paramjeet, Andreas Boes, Guanghui Ren, Thach G. Nguyen, Gunther Roelkens, and Arnan Mitchell. “Hybrid and Heterogeneous Photonic Integration.” APL Photonics 6, no. 6 (Jun. 1, 2021): 061102. https://doi.org/10.1063/5.0052700.
[8] Sekine, Ryoto, Robert M. Gray, Luis Ledezma, Selina Zhou, Qiushi Guo, and Alireza Marandi. “Multi-Octave Frequency Comb from an Ultra-Low-Threshold Nanophotonic Parametric Oscillator.” ar Xiv, Sep. 8, 2023. http://arxiv.org/abs/2309.04545.
[9] R. M. Gray, et al. Large-scale time-multiplexed nanophotonic parametric oscillators. arXiv: 2405.17355 (2024)
[10] Churaev, Mikhail, Rui Ning Wang, Annina Riedhauser, Viacheslav Snigirev, Terence Blésin, Charles Mohl, Miles H. Anderson, et al. “A Heterogeneously Integrated Lithium Niobate-on-Silicon Nitride Photonic Platform.” Nature Communications 14, no. 1 (Jun. 13, 2023): 3499. https://doi.org/10.1038/s41467-023-39047-7.
[11] Vandekerckhove, Tom, Tom Vanackere, Jasper De Witte, Stijn Cuyvers, Luis Reis, Maximilien Billet, Günther Roelkens, Stéphane Clemmen, and Bart Kuyken. “Reliable Micro-Transfer Printing Method for Heterogeneous Integration of Lithium Niobate and Semiconductor Thin Films.” Optical Materials Express 13, no. 7 (Jul. 1, 2023): 1984. https://doi.org/10.1364/OME.494038.
[12] Ledezma, Luis, Ryoto Sekine, Qiushi Guo, Rajveer Nehra, Saman Jahani, and Alireza Marandi. “Intense Optical Parametric Amplification in Dispersion-Engineered Nanophotonic Lithium Niobate Waveguides.” Optica 9, no. 3 (Mar. 20, 2022): 303. https://doi.org/10.1364/OPTICA.442332.
[13] Op De Beeck, Camiel, Bahawal Haq, Lukas Elsinger, Agnieszka Gocalinska, Emanuele Pelucchi, Brian Corbett, Günther Roelkens, and Bart Kuyken. “Heterogeneous III-V on Silicon Nitride Amplifiers and Lasers via Microtransfer Printing.” Optica 7, no. 5 (May 20, 2020): 386. https://doi.org/10.1364/OPTICA.382989.
[14] Op De Beeck, Camiel, Felix M. Mayor, Stijn Cuyvers, Stijn Poelman, Jason F. Herrmann, Okan Atalar, Timothy P. McKenna, et al. “III/V-on-Lithium Niobate Amplifiers and Lasers.” Optica 8, no. 10 (Oct. 20, 2021): 1288. https://doi.org/10.1364/OPTICA.438620.
[15] Komljenovic, Tin, Michael Davenport, Jared Hulme, Alan Y. Liu, Christos T. Santis, Alexander Spott, Sudharsanan Srinivasan, Eric J. Stanton, Chong Zhang, and John E. Bowers. “Heterogeneous Silicon Photonic Integrated Circuits.” Journal of Lightwave Technology 34, no. 1 (January 2016): 20-35. https://doi.org/10.1109/JLT.2015.2465382.
[16] Liu, Yang, Zheru Qiu, Xinru Ji, Anton Lukashchuk, Jijun He, Johann Riemensberger, Martin Hafermann, et al. “A Photonic Integrated Circuit-Based Erbium-Doped Amplifier.” Science 376, no. 6599 (Jun. 17, 2022): 1309-13. https://doi.org/10.1126/science.abo2631.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A photonic integrated circuit comprising:
at least one integrated optical gain section having a peak gain at a first frequency; and
at least one nonlinear sub-circuit which is coupled to the optical gain section either evanescently or through edge coupling, wherein:
the nonlinear sub-circuit further comprises:
at least one nonlinear component comprising at least one of a waveguide or a resonator comprising second-order nonlinearity enabling generation of frequency components at least one octave below or above the first frequency, and
the nonlinear sub-circuit is configured to provide at least one of:
nonlinear interferometry, wherein the non-linear sub-circuit comprises an interferometer having an interferometer output depending on an input intensity to the nonlinear sub-circuit, or
spectral broadening by extending a spectrum outside a gain spectrum of the optical gain section.

2. The circuit of claim 1, wherein the optical gain section comprises a semiconductor optical amplifier which is electrically pumped.

3. The circuit of claim 1 wherein the optical gain section comprises a rare-earth doped material which is optically pumped.

4. The circuit of claim 1, wherein the nonlinear sub-circuit comprises the nonlinear component comprising a section configured to provide phase matching or a certain level of phase mismatch for one or a plurality of quadratic nonlinear processes.

5. The circuit of claim 4, wherein the nonlinear component comprises a section made of a ferroelectric material and the phase matching is provided by periodic or aperiodic poling of the ferroelectric domains of the ferroelectric material.

6. The circuit of claim 1, wherein the nonlinear sub-circuit comprises a Michelson interferometer comprising
a two-by-two coupler comprising coupler ports wherein two of the coupler ports are terminated by mirrors, and at least one of the arms of the interferometer comprises the waveguide comprising a waveguide section with the second order (quadratic) nonlinearity configured to provide phase matched or phase mismatched second-harmonic generation in the vicinity of the first frequency.

7. The circuit of claim 1, wherein the nonlinear subcircuit comprises a Mach-Zehnder interferometer comprising:
two two-by-two couplers which are connected to each other in series via connecting waveguide, and one of the connecting waveguides includes the waveguide comprising a waveguide section with the second order (quadratic) nonlinearity configured to provide phase matched or phase mismatched second-harmonic generation in the vicinity of the first frequency.

8. The circuit of claim 7, wherein the Mach-Zehnder nonlinear interferometer is terminated by a partial or almost perfect loop mirror or other types of reflectors.

9. The circuit of claim 7, wherein the Mach-Zehnder nonlinear interferometer is placed inside a laser resonator configured as a ring or linear resonator comprising the gain element.

10. The circuit of claim 1, wherein the nonlinear sub-circuit comprises the at least one nonlinear component comprising at least two spectral broadening sections and two filters and is configured as a Mamyshev oscillator to generate short pulses.

11. The circuit of claim 1, wherein the nonlinear sub-circuit further comprises an actuator, in the form of an electro-optic or thermo-optic or piezoelectric modulator.

12. The circuit of claim 11, wherein the actuator is an electrooptic modulator which is configured to be driven at frequencies from DC to 10's of GHz or a portion of this range.

13. The circuit of claim 1 wherein the nonlinear sub-circuit comprises an optical parametric oscillator.

14. The circuit of claim 1, wherein the nonlinear sub-circuit comprises a coupler for coupling to the resonator or the waveguide, the photonic integrated circuit further comprising at least one mode converter and at least one spatial filter coupled to match the spatial modes of electromagnetic pulses between the coupler, the gain section, and the nonlinear component comprising the waveguide.

15. The circuit of claim 1, wherein the one or a plurality of waveguides in the nonlinear sub-circuit are dispersion-engineered for specific group velocity dispersions and/or group velocity mismatch among different spectral contents of electromagnetic waves generated in the nonlinear sub-circuit to enable formation of electromagnetic pulses shorter than 100 picoseconds (ps) in the circuit or spectra of the electromagnetic wave spanning beyond an octave.

16. The circuit of claim 1, wherein the nonlinear sub-circuit is configured to create a passively mode-locked laser generating electromagnetic pulses shorter than 20 picoseconds (ps).

17. The circuit of claim 1, wherein the nonlinear sub-circuit is configured to create an electro-optic frequency comb source wherein the source comprises a laser cavity comprising the gain element and one or a plurality of electro-optic modulators in the nonlinear sub-circuit.

18. The circuit of claim wherein the spectral broadening is covering one octave or ⅔ of an octave, and the circuit is further configured to provide a self-referenced frequency comb through f-2f or 2f-3f interferometry.

19. The circuit of claim 1 wherein the non-linear sub-circuit comprises the resonator comprising parametrically driven active cavity comprising a coupler comprising wavelength selective coupler coupling the optical gain section to the waveguide configured to generate a half frequency of a pump, wherein the optical gain section is configured to amplify the half frequency and the coupler is designed to transmit the half frequency but not the pump inputted to the non-linear sub-circuit.

20. The circuit of claim 1, wherein the nonlinear sub-circuit is configured to support formation of solitons.
